(19) United States
(12) Patent Application Publication
(10) Pub. No.: US 2021/0036263 A1
(43) Pub. Date: Feb. 4, 2021

(54) DISPLAY DEVICE AND METHOD OF MANUFACTURING THE DISPLAY DEVICE

(71) Applicant: Samsung Display Co., Ltd., Yongin-si (KR)

(72) Inventors: Myung Hwan KIM, Yongin-si (KR); Sang Yeol KIM, Hwaseong-si (KR); Chang Han LEE, Cheonan-si (KR); Ho Ryun CHUNG, Suwon-si (KR)

(21) Appl. No.: 16/840,022

(22) Filed: Apr. 3, 2020

(30) Foreign Application Priority Data
Aug. 2, 2019 (KR) 10-2019-0094517

(51) Int. Cl. H01L 51/52; H01L 27/32; H01L 51/56

(52) U.S. Cl. CPC H01L 51/5281; H01L 27/3246; H01L 27/323; H01L 2227/323; H01L 51/56; H01L 51/5237; H01L 51/5293

(57) ABSTRACT

A display includes: a display member at which a plurality of pixels are defined, the display member including a base substrate, a light-emitting element on the base substrate at each pixel, and a thin film encapsulation layer on the light-emitting element; a viewing angle controlling member on the display member, the viewing angle controlling member including a plurality of viewing angle controlling patterns; and a cover window on the plurality of viewing angle controlling patterns. The plurality of viewing angle controlling patterns are directly on the thin film encapsulation layer.

### CROSS-REFERENCE TO RELATED APPLICATION

This application claims priority to and the benefit of Korean Patent Application No. 10-2019-0094517, filed on Aug. 2, 2019 in the Korean Intellectual Property Office, the disclosure of which is incorporated herein by reference in its entirety.

### BACKGROUND

### 1. Field

Aspects of embodiments of the present disclosure relate to a display and a method of manufacturing the same.

### 2. Description of the Related Art

Displays are apparatuses for displaying an image, and each display includes a display panel such as an organic light-emitting display panel and/or a liquid crystal panel. Displays may include a window for protecting a display panel from an external impact. Particularly, such windows are generally applied to portable electronic devices, for example, such as smart phones and the like. Some portable electronic devices utilize a touch input function. The displays of such portable electronic devices may include a touch panel to perform the touch input function. The window, touch panel, and display panel may be attached to each other through adhesives and/or the like.

The above information disclosed in this Background section is for enhancement of understanding of the background of the present disclosure, and therefore, it may contain information that does not constitute prior art.

### SUMMARY

One or more exemplary embodiments of the present disclosure are directed to a display in which a viewing angle controlling pattern is embedded in a display panel.

One or more exemplary embodiments of the present disclosure are directed to a method of manufacturing a display in which a viewing angle controlling pattern is embedded in a display panel.

It should be noted that aspects and features of the present disclosure are not limited to the above-described aspects and features, and other aspects and features of the present disclosure will be apparent to those skilled in the art from the following description.

According to an example embodiment of the present disclosure, a display includes: a display member at which a plurality of pixels are defined, the display member including a base substrate, a light-emitting element on the base substrate at each pixel, and a thin film encapsulation layer on the light-emitting element; a viewing angle controlling member on the display member, the viewing angle controlling member including a plurality of viewing angle controlling patterns; and a cover window on the plurality of viewing angle controlling patterns. The plurality of viewing angle controlling patterns are directly on the thin film encapsulation layer.

In an embodiment, the viewing angle controlling patterns may include at least one of a black-based dye and a metal.

In an embodiment, the viewing angle controlling member may further include a light transmission pattern between adjacent ones of the viewing angle controlling patterns, the light transmission pattern including a transparent photosensitive material.

In an embodiment, a height of at least one of the viewing angle controlling patterns may be equal to two or three times a pitch between the adjacent ones of the viewing angle controlling patterns.

In an embodiment, at least one of the viewing angle controlling patterns may have a forward-tapered shape, and an inclined angle between a top surface of the thin film encapsulation layer and a side surface of the at least one of the viewing angle controlling patterns may be within a range of 91° to 110°.

In an embodiment, at least one of the viewing angle controlling patterns may have a reverse-tapered shape, and an inclined angle between a top surface of the thin film encapsulation layer and a side surface of the at least one of the viewing angle controlling patterns may be within a range of 85° to 89°.

In an embodiment, a height of a surface of at least one of the viewing angle controlling patterns may be less than a height of a surface of the light transmission pattern.

In an embodiment, the surface of the at least one of the viewing angle controlling patterns may include a concave shape or a convex shape.

In an embodiment, a height of a surface of at least one of the viewing angle controlling patterns may be greater than a height of a surface of the light transmission pattern, and the at least one of the viewing angle controlling patterns may partially cover a top surface of the light transmission pattern.

In an embodiment, the light-emitting element may include a first electrode on the base substrate, a second electrode opposite to the first electrode, and a light-emitting layer between the first electrode and the second electrode, and each of the pixels may include a light-emitting area at which a top surface of the first electrode is partially exposed by a pixel definition film on the first electrode, a non-emitting area may be defined at a periphery of the light-emitting area, and each of the viewing angle controlling patterns may be at the non-emitting area.

In an embodiment, each of the viewing angle controlling patterns may not overlap with the light-emitting area of an adjacent pixel.

In an embodiment, a height of the viewing angle controlling patterns may be greater than a width of the light-emitting area of an adjacent pixel.

In an embodiment, each of the pixels may include a light-exit area including the light-emitting area and a non-exit area at a periphery of the light-exit area, the display may further include a light-barrier pattern at the non-exit area on the cover window, and the light-barrier pattern may overlap with a corresponding one of the viewing angle controlling patterns in a thickness direction.

In an embodiment, the display may further include: long-side edges extending in a first direction; and short-side edges extending in a second direction crossing the first direction. The plurality of viewing angle controlling patterns may have a stripe shape extending in the first direction.

In an embodiment, the viewing angle controlling patterns may be continuously arranged on a border along the long-side edges and the short-side edges.

In an embodiment, the display may further include: long-side edges extending in a first direction; and short-side edges extending in a second direction crossing the first direction. The plurality of viewing angle controlling patterns may have a stripe shape extending in the second direction.

In an embodiment, the display may further include: long-side edges extending in a first direction; and short-side edges extending in a second direction crossing the first direction. The plurality of viewing angle controlling patterns may have a lattice shape extending in the first direction and the second direction.

In an embodiment, the display may further include a through-hole extending through the display member and the viewing angle controlling member in a thickness direction, and the viewing angle controlling patterns may surround the through-hole.

In an embodiment, the display may further include: a touch member on the plurality of viewing angle controlling patterns; and a polarization layer on the touch member.

According to an example embodiment of the present disclosure, a display includes: a display member at which a plurality of pixels are defined, the display member including a base substrate, a light-emitting element on the base substrate at each pixel, and a thin film encapsulation layer on the light-emitting element; a touch member on the display member; a polarization layer on the touch member; a viewing angle controlling member on the display member, the viewing angle controlling member including a plurality of viewing angle controlling patterns; and a cover window on the plurality of viewing angle controlling patterns. The light-emitting element includes: a first electrode on the base substrate; a second electrode opposite to the first electrode; and a light-emitting layer between the first electrode and the second electrode. Each of the pixels includes a light-emitting area at which a top surface of the first electrode is partially exposed by a pixel definition film on the first electrode, a non-emitting area is defined at a periphery of the light-emitting area, and each of the viewing angle controlling patterns is at the non-emitting area. Each of the viewing angle controlling patterns does not overlap with the light-emitting area of an adjacent pixel.

In an embodiment, the viewing angle controlling patterns may include at least one of a black-based dye, a black-based pigment, and a metal.

In an embodiment, the viewing angle controlling member may further include a light transmission pattern between adjacent ones of the viewing angle controlling patterns, the light transmission pattern including a transparent photosensitive material.

In an embodiment, the viewing angle controlling member may be between the touch member and the polarization layer, or the viewing angle controlling member may be between the polarization layer and the cover window.

According to an example embodiment of the present disclosure, a method of manufacturing a display, includes: providing a display member including a base substrate, a light-emitting element on the base substrate in each pixel, and a thin film encapsulation layer on the light-emitting element; forming a photoresist directly on the thin film encapsulation layer; forming a plurality of light transmission patterns by exposing the photoresist to light and developing the exposed photoresist; and forming a viewing angle controlling pattern between adjacent ones of the light transmission patterns. The viewing angle controlling pattern is in direct contact with the thin film encapsulation layer.

In an embodiment, the exposing of the photoresist may include positively exposing the photoresist using a mask, or negatively exposing the photoresist using a mask.

In an embodiment, the forming of the viewing angle controlling pattern between adjacent ones of the light transmission patterns may include forming the viewing angle controlling pattern between adjacent ones of the light transmission patterns through an inkjet process or through a filling process using a black-based material.

Other aspects and features of exemplary embodiments may be included in the detailed description with reference to the attached drawings.

### BRIEF DESCRIPTION OF THE DRAWINGS

The above and other aspects and features of the present disclosure will become more apparent to those skilled in the art from the following detailed description of the illustrative, non-limiting exemplary embodiments with reference to the attached drawings, in which:

FIG. 1 is a perspective view of a display according to an embodiment;

FIG. 2 is a cross-sectional view of the display taken along the line II-II′ of FIG. 1;

FIG. 3 is a more detailed cross-sectional view of the display of FIG. 2;

FIG. 4 is an arrangement plan view of the display according to an embodiment;

FIG. 5 is a more detailed cross-sectional view of the display of FIG. 3;

FIG. 6 is an arrangement plan view of a touch member according to an embodiment.

FIG. 7 is a cross-sectional view illustrating a thin film encapsulation layer, a viewing angle controlling member, and the touch member according to an embodiment;

FIG. 8 is a cross-sectional view illustrating a thin film encapsulation layer, a viewing angle controlling member, and a touch member according to an embodiment;

FIG. 9 is a cross-sectional view illustrating a thin film encapsulation layer, a viewing angle controlling member, and a touch member according to an embodiment;

FIG. 10 is a cross-sectional view illustrating a thin film encapsulation layer, a viewing angle controlling member, and a touch member according to an embodiment;

FIG. 11 is a cross-sectional view illustrating a thin film encapsulation layer, a viewing angle controlling member, and a touch member according to an embodiment;

FIG. 12 is a cross-sectional view illustrating a thin film encapsulation layer, a viewing angle controlling member, and a touch member according to an embodiment;

FIGS. 13-16 are cross-sectional views of a plurality of processing operations of a method of manufacturing a display according to an embodiment;

FIGS. 17-18 are cross-sectional views of a plurality of processing operations of a method of manufacturing a display according to an embodiment;

FIG. 19 is a cross-sectional view illustrating a processing operation of the method of manufacturing the display according to an embodiment;

FIG. 20 is a perspective view of a display according to an embodiment;

FIG. 21 is a cross-sectional view of the display taken along the line XXII-XXII′ of FIG. 20;

FIG. 22 is a cross-sectional view of a display according to an embodiment;

FIG. 23 is a cross-sectional view of a display according to an embodiment;

FIG. 24 is a cross-sectional view of a display according to an embodiment;

FIG. 25 is an arrangement plan view of a display according to an embodiment; and

FIG. 26 is an arrangement plan view of a display according to an embodiment.

### DETAILED DESCRIPTION

Hereinafter, example embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” “has, ” “have, ” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration. Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

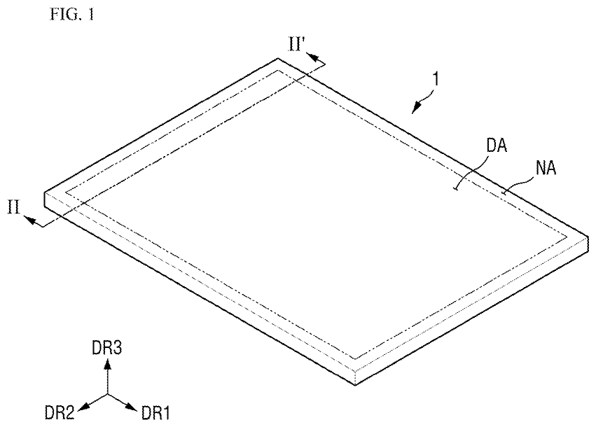

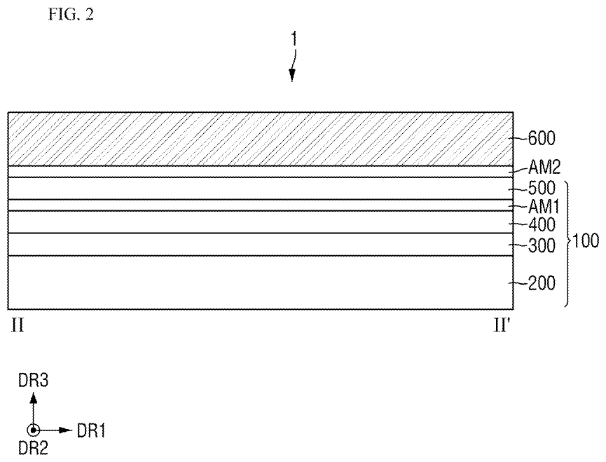

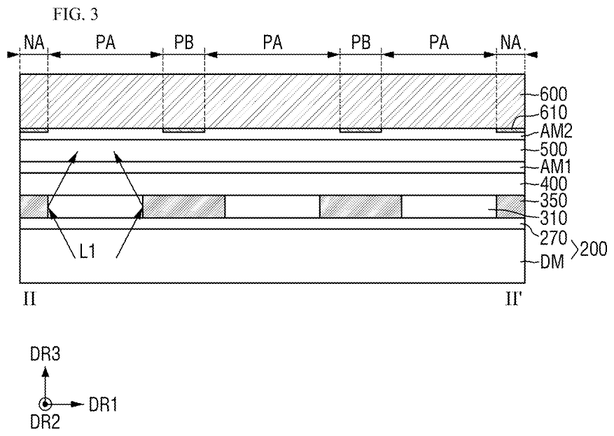

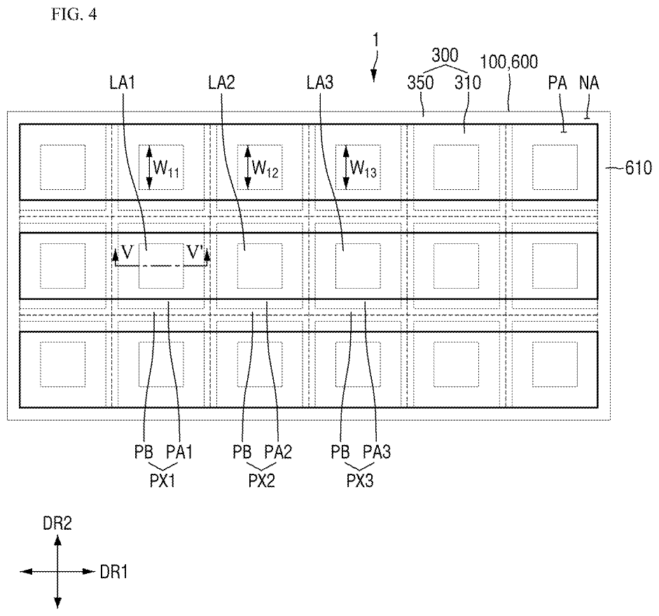

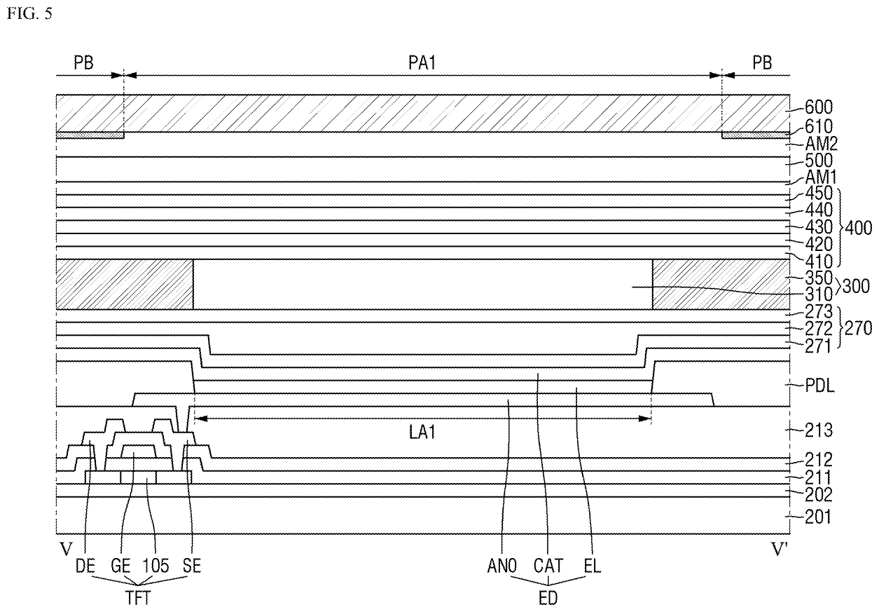

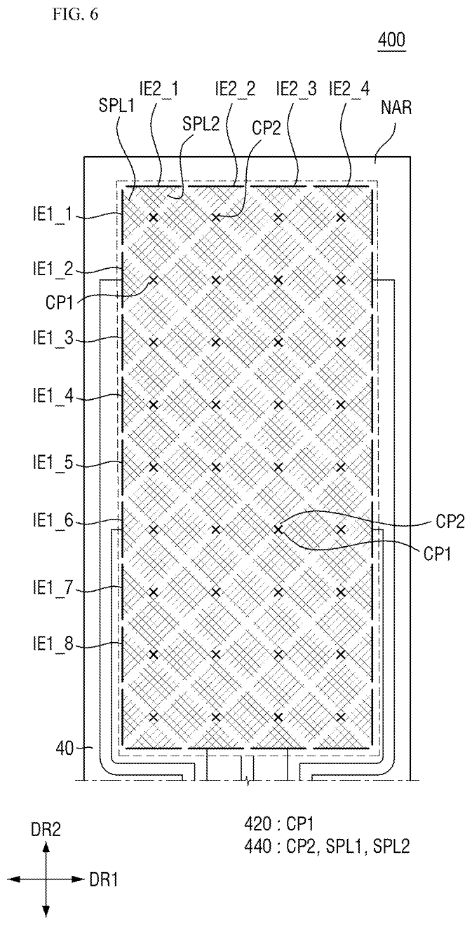

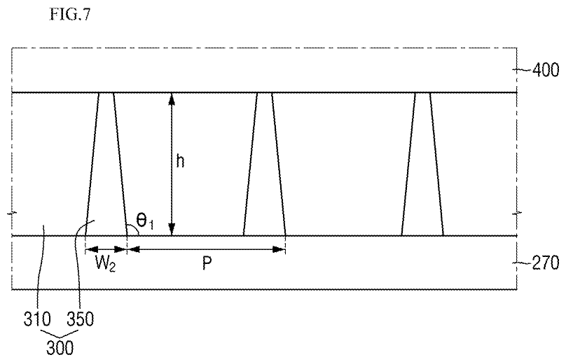

FIG. 1 is a perspective view of a display device according to an embodiment. FIG. 2 is a cross-sectional view of the display device taken along the line II-11′ of FIG. 1. FIG. 3 is a more detailed cross-sectional view of the display of FIG. 2. FIG. 4 is an arrangement plan view of the display according to an embodiment. FIG. 5 is a more detailed cross-sectional view of the display of FIG. 3. FIG. 6 is an arrangement plan view of a touch member according to an embodiment. FIG. 7 is a cross-sectional view illustrating a thin film encapsulation layer, a viewing angle controlling member, and the touch member according to an embodiment.

As used herein, a display (e.g., a display 1) is a device that displays a moving picture or a still image, and may be used as a display screen of a variety of products, for example, such as for various portable electronic devices and/or for various display devices. Examples of such portable electronic devices may include a mobile phone, a smart phone, a tablet personal computer (PC), a smart watch, a watch phone, a mobile communication terminal, an electronic notebook, an electronic book, a portable multimedia player (PMP), a navigation system, an ultra-mobile PC, and/or the like. Example of such display devices may include a television, a laptop PC, a monitor, an advertising panel, an Internet of Things (IoT) device, and/or the like. In an exemplary embodiment, the display 1 may be a display for a vehicle (e.g., a vehicular display), but the present disclosure is not limited thereto.

Referring to FIGS. 1 to 7, the display 1 may have a rectangular shape in a plan view. As used herein, a plan view may refer to a view from a plane that is perpendicular to or substantially perpendicular to (e.g., or normal to) a top surface of the relevant component, element, layer, region, area, and/or the like (e.g., a top surface of the display 1). When a rectangular shape is applied as a planar shape (e.g., a shape when viewed from the plan view) of the display 1, the display 1 may include a plurality of long-side edges extending along a first direction DR1 and a plurality of short-side edges extending along a second direction DR2 that crosses the first direction DR1. Corners where the long-side edges are connected to (e.g., contact or meet with) the short-side edges may have an angular shape as shown in FIG. 1, but the present disclosure is not limited thereto, and one or more of the corners may have a rounded shape. However, the present disclosure is not limited to the rectangular shape as the planar shape of the display 1, and in some embodiments, the planar shape of the display 1 may include any suitable or desired shape, for example, such as a square shape, a circular shape, an elliptical shape, other polygonal shapes, and/or the like.

The display 1 may include a display area DA located at (e.g., in or on) a central part (e.g., a central area) of the display 1 in a plan view, and a non-display area NDA located at (e.g., in or on) a periphery of the display area DA. For example, in some embodiments, the non-display area NDA may surround (e.g., around a periphery of) the display area DA. The non-display area NA may be a bezel area, which does not display an image. The display area DA may be an area including a plurality of pixels, and displays an image.

A planar shape (e.g., a shape when viewed from a plan view) of the display area DA may be the same or substantially the same as (e.g., generally equal to or substantially similar to) the shape (e.g., the planar shape) of the display 1. In other words, in an embodiment, the planar shape of the display area DA may be a rectangular shape with angular corners. In this case, the non-display area NA may be disposed along each of (e.g., on all of) a plurality of long-side edges and a plurality of short-side edges of the display area DA to be disposed (e.g., continuously disposed) at (e.g., on) an edge area (e.g., a bezel area) of the display 1, but the present disclosure is not limited thereto. For example, in various embodiments, the non-display area NA may be disposed along (e.g., in or on) only one long-side edge, one short-side edge, one long-side edge and one short-side edge, both long-side edges, both short-side edges, and/or the like of the display 1.

The display 1 includes a display panel 100, and a cover window 600 disposed on the display panel 100 to cover and protect the display panel 100. The display panel 100 may include a display member 200, a viewing angle controlling member 300 disposed on the display member 200, a touch member 400 disposed on the viewing angle controlling member 300, and an optical film 500 disposed on the touch member 400.

The touch member 400 and the optical film 500 may be coupled with each other through a first optically transparent adhesive member AM1 that is interposed therebetween, and the optical film 500 and the cover window 600 may be coupled with each other through a second optically transparent adhesive member AM2 that is interposed therebetween. In other words, the first optically transparent adhesive member AM1 may connect (e.g., or attach) the touch member 400 and the optical film 500 to each other, and the second optically transparent adhesive member AM2 may connect (e.g., or attach) the optical film 500 and the cover window 600 to each other. Each of the first optically transparent adhesive member AM1 and the second optically transparent adhesive member AM2 may include an optically transparent adhesive film, an optically transparent adhesive tape, an optically transparent resin, and/or the like.

The display panel 100 is a panel which displays an image according to an input data signal. For example, in an embodiment, the display panel 100 may include an organic light-emitting display panel. However, while the organic light-emitting display panel is described in the following embodiments as a non-limiting example of the display panel 100, the present disclosure is not limited thereto, and any other suitable kinds of display panels may be applied as the display panel 100 as would be known to those skilled in the art, for example, such as a liquid crystal display (LCD) panel, a quantum dot organic light emitting diode (QD-OLED) display panel, a QD-LCD panel, a quantum nano light emitting diode (LED) panel, a micro LED panel, and/or the like.

The display area DA of the display member 200 includes a plurality of pixels. Each pixel may include a light-emitting layer, and a circuit layer that controls a light-emitting quantity of the light-emitting layer. The circuit layer may include a display wiring, a display electrode, and at least one transistor. The light-emitting layer may include an organic light-emitting material. The light emitting layer may be sealed by an encapsulation film. The encapsulation film may prevent or substantially prevent humidity and/or the like from penetrating (e.g., or from flowing) into the light emitting layer from the outside by sealing the light-emitting layer. The encapsulation film may include a single layer inorganic film or lamination film, or a multilayered inorganic film or lamination film that is formed by alternately laminating an inorganic film and an organic film.

The non-display area NA of the display member 200 may include a driving wiring that is connected to the display wiring of the pixel, and a pad (e.g., a driving wiring pad) of the driving wiring. One or more external components, for example, such as a driving chip, a printed circuit board (PCB), and/or the like, may be mounted on the driving wiring pad as described in more detail below.

A thin film encapsulation layer 270 may be disposed on an upper part (e.g., on an uppermost part) of the display member 200. For example, the thin film encapsulation layer 270 may be disposed on light-emitting elements of the display member 200, and may cover the light-emitting elements. The thin film encapsulation layer 270 may include (or may be) a lamination film formed by alternately laminating an inorganic film and an organic film. For example, the thin film encapsulation layer 270 may include a first inorganic encapsulation film 271 (refer to FIG. 5), an organic encapsulation film 272 (refer to FIG. 5), and a second inorganic encapsulation film 273 (refer to FIG. 5), which are sequentially laminated.

Hereinafter, the components of the display member 200 may be referred to as lower display members DM, except for the thin film encapsulation layer 270.

A more detailed description of the display member 200 will be set forth below.

The touch member 400 may be disposed on the display member 200. The touch member 400 may sense a touch pressure. The touch member 400 may be provided in the form of a touch layer inside the display panel 100. However, the present disclosure is not limited thereto, and while a case in which the touch member 400 is provided inside the display panel 100 is described as an example in the following embodiment, the touch member 400 may be provided as a separate panel or film and attached to the display panel 100 as would be understood by those skilled in the art.

A more detailed description of the touch member 400 will be set forth below.

The optical film 500 may be disposed on the touch member 400. The optical film 500 may include a plurality of laminated films. For example, the optical film 500 may include a lower protection film disposed on the touch member 400, a phase-delay film disposed on the lower protection film, a polarization layer disposed on the phase-delay film, and an upper protection film disposed on the polarization layer.

The upper protection film and the lower protection film may protect the polarization layer and the phase-delay film from external humidity, foreign substances, and/or the like. The upper protection film and the lower protection film may include an organic insulating material.

The phase-delay film may shift a phase of light. For example, the phase-delay film may include (or may be) a λ/4 (e.g., a quarter-wave) phase-delay film. The phase-delay film may include a double-refractive film including a polymer, an orientation film of a liquid polymer, a film including an orientation layer of a liquid polymer, and/or the like.

The polarization layer may selectively transmit light. For example, the polarization layer may include (or may be) a linear polarization layer. The polarization layer may include (or may be) a polyvinyl alcohol (PVA) film. The polarization layer may be manufactured by elongating the PVA film in a desired direction (e.g., in one direction or in an elongation direction), and then adsorbing iodine (I) and/or a dichromatic dye therein. In this case, the polarization layer may have an absorption axis in the elongation direction, and a transmission axis in a direction perpendicular to or substantially perpendicular to (or normal to) an absorption axis. Accordingly, linear polarized light from among light that is incident on the polarization layer (e.g., only the linear polarized light) is emitted in a direction that is parallel to or substantially parallel to the transmission axis.

The cover window 600 is disposed above (e.g., on) the display panel 100. The cover window 600 is disposed above the display panel 100 to protect the display panel 100, while transmitting light that is emitted from the display panel 100. The cover window 600 may include glass and/or the like.

The cover window 600 may be disposed to overlap with the display panel 100, and may cover an entire surface of the display panel 100. In some embodiments, the cover window 600 may be larger than the display panel 100. For example, in some embodiments, the cover window 600 may protrude further outwardly from both short sides of the display 1 than the display panel 100.

The viewing angle controlling member 300 may be disposed between the display member 200 and the touch member 400. As shown in FIG. 3, the viewing angle controlling member 300 may include light transmission patterns 310, and viewing angle controlling patterns 350 that are disposed between adjacent ones of the light transmission patterns 310.

The light transmission patterns 310 may transmit light emitted by the light-emitting elements to allow a user to recognize the light. The light transmission patterns 310 may include a transparent material. The transparent material may include, for example, a resin and/or a transparent photosensitive material. The resin may include, for example, polyethylene terephthalate (PET), polyacrylate, polyimide (PI), polycarbonate (PC), and/or the like. The transparent photosensitive material may include (or may be), for example, a photoresist. According to an embodiment, the light transmission pattern 310 may include a photoresist.

The viewing angle controlling pattern 350 may adjust a viewing angle (e.g., a particular viewing angle) to prevent or substantially prevent light that is emitted by the light-emitting element from being emitted greater than a desired angle (e.g., a particular angle or a threshold angle) that may be recognized by the user. The viewing angle controlling pattern 350 may, for example, convert an optical path by reflecting a first light ray L1 that is emitted from the light-emitting element to adjust the viewing angle (e.g., the particular viewing angle). The viewing angle controlling pattern 350 may include a light-barrier material and/or a light-reflecting material. The light barrier material may include various suitable materials, for example, such as a dark-colored pigment (e.g., a black pigment and/or a gray pigment), a dark-colored dye (e.g., a black dye and/or a gray dye), carbon black, a photoresist, and/or the like. The light-reflecting material may include various suitable materials, for example, such as a metal material (e.g., aluminum (Al) and/or silver (Ag)).

Each pixel of the display 1 may include a light-exit area PA, and a non-exit area PB located at (e.g., on) a periphery of (e.g., or located adjacent to) the light-exit area PA. The light-exit area PA and the non-exit area PB may be divided by a light-barrier member 610, which will be described in more detail below. The light-barrier member 610 may be disposed on a bottom surface of the cover window 600. For example, the light-barrier member 610 may be printed on (e.g., printed directly on) the bottom surface of the cover window 600. The light-barrier member 610 may be disposed over the non-exit area PB and the non-display area NA, and may not be disposed at (e.g., in or on) the light-exit area PA.

The above-described viewing angle controlling pattern 350 may be disposed to overlap with the light-barrier member 610 in a thickness direction (e.g., in a direction that is parallel or substantially parallel to (e.g., or normal with) a top surface of the display 1). The viewing angle controlling pattern 350 may be disposed at (e.g., in or on) the non-display area NA and the non-exit area PB. As shown in FIG. 3, in some embodiments, the viewing angle controlling pattern 350 may be disposed to extend to the light-exit area PA that is adjacent to the non-exit area PB. For example, in some embodiments, the viewing angle controlling pattern 350 may partially overlap with the light-exit area PA. In other words, the viewing angle controlling pattern 350 may be disposed at (e.g., in or on) the non-exit area PB, and at (e.g., in or on) a part (or a portion) of the light-exit area PA. The viewing angle controlling pattern 350 may have a width that is greater than a width of the light-barrier member 610 at (e.g., in or on) the display area DA. In other words, side surfaces (e.g., opposite end surfaces shown in FIG. 3) of the viewing angle controlling pattern 350 may be located further outside than side surfaces (e.g., opposite end surfaces shown in FIG. 3) of the light-barrier member 610 in a plan view.

Referring to FIG. 4, a plurality of pixels PX1, PX2, and PX3 of the display area DA may include a first pixel PX1 to emit a first color light (for example, a red color light having a wavelength peak within a range of about 610 nm to about 650 nm), a second pixel PX2 to emit a second color light (for example, a green color light having a wavelength peak within a range of about 510 nm to about 550 nm), and a third pixel PX3 to emit a third color light (for example, a blue color light having a wavelength peak within a range of about 430 nm to about 470 nm). The first pixel PX1, the second pixel PX2, and the third pixel PX3 may be alternately arranged with each other in a row direction and/or a column direction. The plurality of pixels PX1, PX2, and PX3 may have various suitable arrangements, for example, such as a stripe type arrangement, a pentile type arrangement, and/or the like.

The pixels PX1, PX2, and PX3 may include light-exit areas PA1, PA2, and PA3, respectively, and non-exit areas PB. As used herein, the light-exit areas PA1, PA2, and PA3 are defined as areas in which light exits through a display surface, and the non-exit areas PB are defined as areas in which light does not exit through the display surface. The non-exit areas PB may be arranged to surround (e.g., around a periphery of) the light-exit areas PA1, PA2, and PA3.

The light-barrier member 610 may be disposed at (e.g., in or on) the non-display area NA and the non-exit areas PB, and the viewing angle controlling patterns 350 may be disposed at (e.g., in or on) the non-display area NA and the non-exit areas PB. The light-barrier member 610 may have a lattice shape in a plan view. The viewing angle controlling patterns 350 may be arranged along the non-display area NA, for example, at an edge (or a bezel) of the display 1, and may have a stripe shape extending along the first direction DR1.

The light-exit areas PA1, PA2, and PA3 may further include light-emitting areas LA1, LA2, and LA3, respectively. Non-emitting areas may be arranged at (e.g., on) a periphery of the light-emitting areas LA1, LA2, and LA3. As used herein, the light-emitting areas LA1 to LA3 may be defined as areas of the pixels PX1 to PX3 in which a first electrode ANO (e.g., refer to FIG. 5, and which will be described in more detail below) is exposed by a pixel definition film PDL. The viewing angle controlling patterns 350 may be disposed between the light-emitting areas LA1 to LA3 of the pixels PX1 to PX3, which are disposed to be adjacent to each other along the second direction DR2. The viewing angle controlling patterns 350 may be disposed to not overlap with the light-emitting areas LA1 to LA3 of the respective pixels PX1 to PX3, and to overlap with the non-emitting areas of the respective pixels PX1 to PX3.

The light-emitting areas LA1 to LA3 of the pixels PX1 to PX3 may have a first width W1. The widths of the light-emitting areas LA1 to LA3 may be different from each other or may be equal or substantially equal to each other. For example, a first light-emitting area LA1 may have a first-first width W11, a second light-emitting area LA2 may have a first-second width W12, and a third light-emitting area LA3 may have a first-third width W13. Although it is shown in FIG. 4 that the first width W1 is a width that extends in the second direction DR2, the present disclosure is not limited thereto, and the first width W1 may refer to a width of a part in which the width of each of the light-emitting areas LA1 to LA3 is the greatest. For example, the first-first width W11 of the first light-emitting area LA1 may be equal to the first-second width W12 of the second light-emitting area LA2, and the first-first width W11 of the first light-emitting area LA1 may be less than the first-third width W13 of the third light-emitting area LA3.

The light transmission pattern 310 may be disposed at (e.g., in or on) an area of the display area DA of the display 1 at (e.g., in or on) which the viewing angle controlling pattern 350 is not disposed. The light transmission pattern 310 may be surrounded (e.g., around a periphery thereof) by the adjacent viewing angle controlling pattern 350.

Referring to FIG. 5, the display member 200 may include a base substrate 201, a plurality of conductive layers, a plurality of insulating layers insulating the conductive layers, an organic layer EL, and the like.

The base substrate 201 is disposed over an entirety of the display area DA and the non-display area NA. The base substrate 201 may support a variety of elements that are disposed thereon (e.g., that are disposed above the base substrate 201). The base substrate 201 may be a flexible substrate or a semiflexible substrate including a partially flexible material (e.g., a semi-flexible material). In this case, the base substrate 201 may include, for example, PET, PI, PC, polyethylene (PE), polypropylene (PP), polysulfone (PSF), poly(methyl methacrylate) (PMMA), triacetyl cellulose (TAC), cyclo olefin polymer (COP), and/or the like.

However, the present disclosure is not limited thereto, and in some embodiments, the base substrate 201 may be a rigid substrate including a rigid material, for example, such as glass (e.g., flexible glass), quartz, and/or the like.

The buffer layer 202 may be disposed on the base substrate 201. The buffer layer 202 may prevent or substantially prevent humidity and/or oxygen from penetrating from the outside through the base substrate 201. The buffer layer 202 may planarize a surface of the base substrate 201. In an embodiment, the buffer layer 202 may include any suitable one from among a silicon nitride (SiNx) film, a silicon oxide (SiO₂) film, and a silicon oxynitride (SiOₓN_{y}) film.

A semiconductor layer 105 may be disposed on the buffer layer 202. The semiconductor layer 105 forms a channel of a thin film transistor (TFT). The semiconductor layer 105 may be disposed at (e.g., in or on) each pixel of the display area DA, and in some embodiments, may be further disposed even at (e.g., in or on) the non-display area NA as needed or desired (e.g., as the occasion demands). The semiconductor layer 105 may include a source/drain area and an active area. The semiconductor layer 105 may include polycrystalline silicon.

A first insulating layer 211 may be disposed on the semiconductor layer 105. The first insulating layer 211 may be disposed on an entire surface of the base substrate 201. The first insulating layer 211 may include (or may be) a gate insulating film having a gate insulating function. The first insulating layer 211 may include one or more of a silicon compound, a metal oxide, and/or the like. For example, the first insulating layer 211 may include silicon oxide, silicon nitride, silicon oxynitride, Al oxide, tantalum (Ta) oxide, hafnium (Hf) oxide, zirconium (Zr) oxide, titanium (Ti) oxide, and/or the like. In some embodiments, one or more of the above described materials that may be included in the first insulating layer 211 may be used alone or in combination with each other.

A gate electrode GE of the TFT may be disposed on the first insulating layer 211. The gate electrode GE may include at least one selected from among molybdenum (Mo), Al, platinum (Pt), palladium (Pd), Ag, magnesium (Mg), gold (Au), nickel (Ni), neodymium (Nd), iridium (Ir), chrome (Cr), calcium (Ca), Ti, tungsten (W), and copper (Cu). The gate electrode GE may be a single film or a lamination film, which may be formed of one or more of the above-exemplified materials.

A second insulating layer 212 may be disposed on the gate electrode GE of the TFT. The second insulating layer 212 may insulate the gate electrode GE, a source electrode SE, and a drain electrode DE of the TFT. The second insulating layer 212 may include one or more materials selected from among the above-exemplified materials of the first insulating layer 211 described above.

The source electrode SE and the drain electrode DE may be disposed on the second insulating layer 212. The source electrode SE and the drain electrode DE may include (or may be) a single film formed of one or more of the above-exemplified materials of the gate electrode GE described above. However, the source electrode SE and the drain electrode DE are not limited thereto, and the source electrode SE and the drain electrode DE may be a lamination film. For example, each of the source electrode SE and the drain electrode DE may have a lamination structure of Ti/Al/Ti, Mo/Al/Mo, Mo/AlGe/Mo, Ti/Cu, and/or the like. The source electrode SE and the drain electrode DE may be in contact with the source area and the drain area, respectively, of the semiconductor layer 105 through respective contact holes that extend (e.g., that pass) through the first insulating layer 211 and the second insulating layer 212.

A third insulating layer 213 may be disposed on the source electrode SE and the drain electrode DE. The third insulating layer 213 may include one or more organic insulating materials, for example, such as polyacrylate resin, epoxy resin, phenolic resin, polyamide resin, polyimide resin, unsaturated polyesters resin, poly phenylenether resin, polyphenylenesulfide resin, benzocyclobutene (BCB), and/or the like. In some embodiments, the third insulating layer 213 may include at least one of the above-exemplified materials of the first insulating layer 211 described above.

The source electrode SE, the drain electrode DE, the gate electrode GE, and the semiconductor layer 105 may form the TFT.

The first electrode ANO is disposed on the third insulating layer 213. The first electrode ANO may be an anode electrode. The first electrode ANO may be electrically connected to the source electrode SE through a contact hole that extends (e.g., passes) through the third insulating layer 213.

The pixel definition film PDL may be disposed on the first electrode layer ANO. The pixel definition film PDL may include an opening that exposes the first electrode layer ANO. The pixel definition film PDL may include an organic insulating material or an inorganic insulating material. In an embodiment, the pixel definition film PDL may include any suitable material, for example, such as a photoresist, a polyimide resin, an acrylic resin, a silicon compound, a polyacrylic resin, and/or the like.

The organic layer EL may be disposed on a top surface of the first electrode ANO, and at (e.g., in or on) the opening of the pixel definition film PDL. A second electrode CAT is disposed on the organic layer EL and the pixel definition film PDL. The second electrode CAT may be a cathode electrode. The cathode electrode CAT may be a common electrode that is disposed over an entirety of the plurality of pixels. The first electrode ANO, the organic layer EL, and the second electrode CAT may form a light-emitting element ED. Each light-emitting element ED may be disposed for each of the pixels PX1, PX2, and PX3.

The thin film encapsulation layer 270 is disposed on the cathode electrode CAT.

The viewing angle controlling member 300 may be disposed on a top surface of the thin film encapsulation layer 270. The viewing angle controlling member 300 may be disposed directly on the top surface of the thin film encapsulation layer 270. In other words, bottom surfaces of the viewing angle controlling pattern 350 and the light transmission pattern 310 may be disposed directly on a top surface of the second inorganic film 273 of the thin film encapsulation layer 270.

The touch member 400 may include a first touch insulating layer 410, a first touch conductive layer 420 disposed on the first touch insulating layer 410, a second touch insulating layer 430 disposed on the first touch conductive layer 420, a second touch conductive layer 440 disposed on the second touch insulating layer 430, and a third touch insulating layer 450 disposed on the second touch conductive layer 440. However, the present disclosure is not limited thereto, and the third touch insulating layer 450 may be omitted as desired.

Referring to FIGS. 5 and 6, the first touch insulating layer 410 may be disposed on the viewing angle controlling member 300. The first touch insulating layer 410 may insulate the first touch conductive layer 420 and a plurality of conductive layers of the display member 200 from each other.

In an embodiment, the first touch insulating layer 410 may include an inorganic insulating material. For example, the inorganic material may include any one or more selected from the group consisting of SiOₓ, SiNₓ, and SiONₓ. In another embodiment, the first touch insulating layer 410 may include an organic material. For example, the organic material may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide resin, and a perylene-based resin.

The first touch conductive layer 420 may be disposed on the first touch insulating layer 410. The first touch conductive layer 420 may include first touch bridge electrodes CP1, which electrically connect adjacent ones of first sensing electrodes IE1_1 to IE1_8 to each other. The first touch bridge electrodes CP1 may be disposed to be spaced apart from each other. The first touch bridge electrodes CP1, which are disposed to be spaced apart from each other, may partially expose a top surface of the first touch insulating layer 410. The first touch bridge electrodes CP1 of the first touch conductive layer 420 may overlap with a black matrix and the pixel definition film PDL. Accordingly, the user may be prevented or substantially prevented from recognizing the first touch bridge electrodes CP1.

The second touch insulating layer 430 may be disposed on the first touch conductive layer 420. The second touch insulating layer 430 may be in contact (e.g., in direct contact) with the first touch insulating layer 410 having the exposed top surface. The second touch insulating layer 430 may insulate the first touch conductive layer 420 and the second touch conductive layer 440 from each other. The second touch insulating layer 430 may include an inorganic insulating material. For example, the second touch insulating layer 430 may include at least one of the exemplified materials of the first touch insulating layer 410 described above.

The second touch conductive layer 440 may be disposed on the second touch insulating layer 430. The second touch conductive layer 440 may include the plurality of first sensing electrodes IE1_1 to IE1_8, a plurality of second sensing electrodes IE2_1 to IE2_4, and second touch bridge electrodes CP2 that electrically connect adjacent ones of the second sensing electrodes IE2_1 to IE2_4 to each other.

The plurality of first sensing electrodes IE1_1 to IE1_8 may extend in the second direction DR2, and may be arranged in the first direction DR1. The plurality of second sensing electrodes IE2_1 to IE2_4 may extend in the first direction DR1, and may be arranged in the second direction DR2.

Each of the plurality of first sensing electrodes IE1_1 to IE1_8 may include a plurality of first sensing lines SPL1 that are arranged to have a mesh shape. Areas partitioned by the plurality of first sensing lines SPL1 may overlap with the light-emitting areas LA1, LA2, and LA3 that are disposed at (e.g., in or on) each pixel.

Each of the plurality of second sensing electrodes IE2_1 to IE2_4 may include a plurality of second sensing lines SPL2 that are arranged to have a mesh shape. Areas partitioned by the plurality of second sensing lines SPL2 may also overlap with the light-emitting areas LA1, LA2, and LA3 that are disposed at (e.g., in or on) each pixel. In an embodiment, the areas partitioned by the plurality of first sensing lines SPL1 and the areas partitioned by the plurality of second sensing lines SPL2 may have a diamond shape. As used herein, the diamond shape includes not only a shape that is the same or substantially the same as a diamond shape, but also a shape that is similar to a diamond shape in consideration of a processing procedure, an arrangement shape of sensing lines, and/or the like.

The plurality of first sensing lines SPL1 may be electrically insulated from the plurality of second sensing lines SPL2. In an embodiment, the plurality of first sensing lines SPL1 and the plurality of second sensing lines SPL2 may be disposed at (e.g., on) the same or substantially the same layer. In this case, the plurality of first touch bridge electrodes CP1 and the plurality of second touch bridge electrodes CP2 are disposed at (e.g., on) different layers from each other, and may be electrically insulated from each other.

The second touch bridge electrodes CP2 and the sensing electrodes of the second touch conductive layer 440 may overlap with a black matrix and the pixel definition film PDL. Accordingly, the user may be prevented or substantially prevented from recognizing the second touch bridge electrodes CP2 and the sensing electrodes.

The third touch insulating layer 450 may be disposed on the second touch conductive layer 440. The third touch insulating layer 450 may include an inorganic material or an organic material.

In some embodiments, the electrodes included in the first touch conductive layer 420 and the electrodes included in the second touch conductive layer 440 may be opposite to each other.

In some embodiments, the first touch conductive layer 420 may include the first sensing electrodes IE1_1 to IE1_8 and the first touch bridge electrodes CP1, and the second touch conductive layer 440 may include the second sensing electrodes IE2_1 to IE2_4 and the second touch bridge electrodes CP2.

In some embodiments, the first touch conductive layer 420 may include the second sensing electrodes IE2_1 to IE2_4 and the second touch bridge electrodes CP2, and the second touch conductive layer 440 may include the first sensing electrodes IE1_1 to IE1_8 and the first touch bridge electrodes CP1.

Hereinafter, for convenience, it may be mainly described that the first touch conductive layer 420 includes the first touch bridge electrodes CP1 that electrically connect the adjacent ones of the first sensing electrodes IE1_1 to IE1_8 to each other, and the second touch conductive layer 440 includes the plurality of first sensing electrodes IE1_1 to IE1_8, the plurality of second sensing electrodes IE2_1 to IE2_4, and the second touch bridge electrodes CP2 that electrically connect the adjacent ones of the second sensing electrodes IE2_1 to IE2_4 to each other.

Each of the first touch conductive layer 420 and the second touch conductive layer 440 may include a conductive material. For example, the conductive material may include a low-resistive metal, such as Ag, Al, Cr, Ni, and/or the like, or the conductive material may include a conductive nano-material, such as silver nanowires, carbon nanotubes, and/or the like.

Referring to FIG. 7, the viewing angle controlling patterns 350 may have a forward-tapered shape. In other words, the viewing angle controlling pattern 350 may have a trapezoidal shape in which a width of a bottom surface thereof is greater than a width of a top surface thereof.

The top surface of the viewing angle controlling pattern 350 may be aligned with a top surface of the light transmission pattern 310. However, the present disclosure is not limited thereto, and the top surface of the viewing angle controlling pattern 350 may protrude upwards from the top surface of the light transmission pattern 310 or may be indented downwards from (e.g., or may be lower than) the top surface of the light transmission pattern 310. The top surface of the viewing angle controlling pattern 350 may have a linear shape.

The viewing angle controlling pattern 350 may have a second width W2 corresponding to a width of the bottom surface thereof, a pitch P between the viewing angle controlling pattern 350 and an adjacent viewing angle controlling pattern 350 on the basis of the bottom surface of the viewing angle controlling pattern 350, and a height h in a thickness direction.

The height h of the viewing angle controlling pattern 350 may be equal to or substantially equal to about two or three times the pitch P of the viewing angle controlling pattern 350. When the viewing angle controlling pattern 350 has the forward-tapered shape, a first inclined angle 81 formed between a side surface of the viewing angle controlling pattern 350 and the top surface of the thin film encapsulation layer 270 may be an obtuse angle. For example, the first inclined angle 81 may be equal to or substantially equal to about 91° to about 110°.

The height h of the viewing angle controlling pattern 350 may be greater than the first width W1 of the light-emitting areas LA1, LA2, and LA3 of each pixel.

In the display 1 according to an embodiment, because the viewing angle controlling member 300 including the viewing angle controlling patterns 350 is embedded in the display panel 100, a distance between the light-emitting element ED of each of the pixels PX1, PX2, and PX3 and the viewing angle controlling pattern 350 may be reduced, so as to adjust (e.g., more easily adjust) a viewing angle.

Also, because the viewing angle controlling member 300 is disposed on (e.g., directly on) the top surface of the thin film encapsulation layer 270 of the display panel 100 without using an adhesive and/or the like, a transmission loss of light that is emitted by the light-emitting element ED of the display panel 100 may be prevented or substantially prevented in advance.

Also, the viewing angle controlling patterns 350 of the viewing angle controlling member 300 may be arranged to not overlap with the light-emitting areas LA1, LA2, and LA3 of the adjacent pixels PX1, PX2, and PX3, so that light loss may be prevented or substantially prevented in advance.

Hereinafter, a display according to one or more other embodiments will be described. In the following description, components, elements, and/or layers that are the same or substantially the same as those of one or more of the above-described embodiments may be referred to with the same or substantially the same reference symbols, and thus, redundant description thereof may be simplified or may not be repeated.

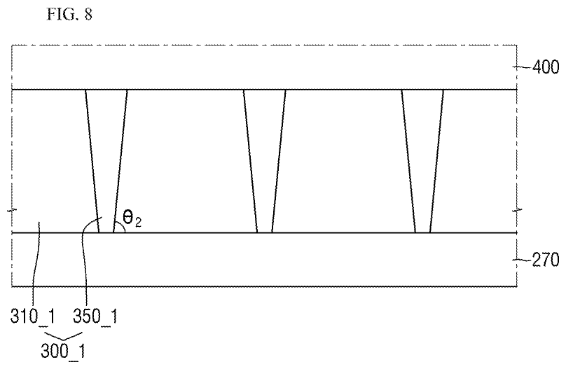

FIG. 8 is a cross-sectional view illustrating a thin film encapsulation layer, a viewing angle controlling member, and a touch member according to an embodiment.

Referring to FIG. 8, a viewing angle controlling member 300_1 may be different from the viewing angle controlling member 300 of FIG. 7 in that a viewing angle controlling pattern 350_1 of the viewing angle controlling member 300_1 of FIG. 8 has a reverse-tapered shape.

When the viewing angle controlling pattern 350_1 has the reverse-tapered shape, a second inclined angle θ2 may be formed between a side surface of the viewing angle controlling pattern 350_1 and the top surface of the thin film encapsulation layer 270. In this case, the second inclined angle θ2 may be an acute angle. For example, the second inclined angle θ2 may be equal to or substantially equal to about 85° to about 89°.

Other components and features in FIG. 8 are the same or substantially the same as those described above with reference to FIG. 7, and thus, redundant description thereof may not be repeated.

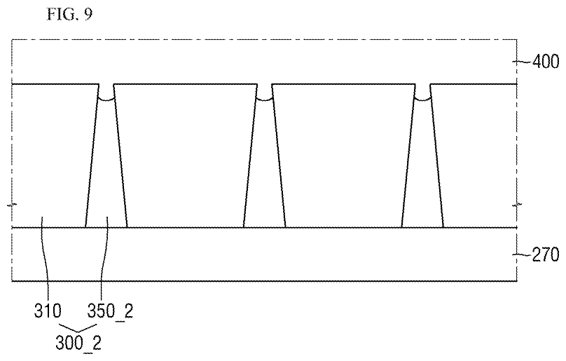

FIG. 9 is a cross-sectional view illustrating a thin film encapsulation layer, a viewing angle controlling member, and a touch member according to an embodiment.

Referring to FIG. 9, a viewing angle controlling member 300_2 according to the embodiment may be different from the viewing angle controlling member 300 of FIG. 7 in that a top surface of a viewing angle controlling pattern 350_2 of the viewing angle controlling member 300_2 in FIG. 9 is indented downwards from the top surface of the light transmission pattern 310. In this case, the top surface of the viewing angle controlling pattern 350_2 may have a concave shape.

Other components and features in FIG. 9 are the same or substantially the same as those described above with reference to FIG. 7, and thus, redundant description thereof may not be repeated.

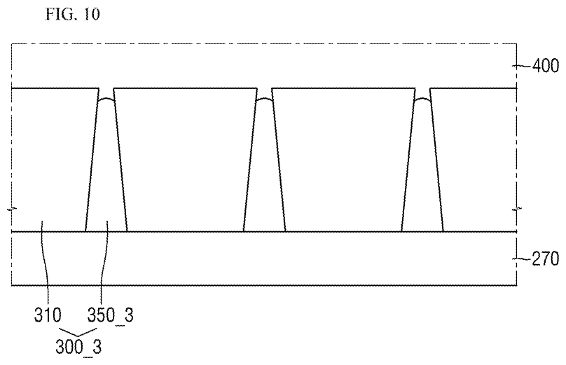

FIG. 10 is a cross-sectional view illustrating a thin film encapsulation layer, a viewing angle controlling member, and a touch member according to an embodiment.

Referring to FIG. 10, a viewing angle controlling member 300_3 according to the embodiment is different from the viewing angle controlling member 300_2 of FIG. 9 in that a viewing angle controlling pattern 350_3 of the viewing angle controlling member 300_3 of FIG. 10 has a convex top surface.

Other components and features in FIG. 10 are the same or substantially the same as those described above with reference to FIGS. 7 and 9, and thus, redundant description thereof may not be repeated.

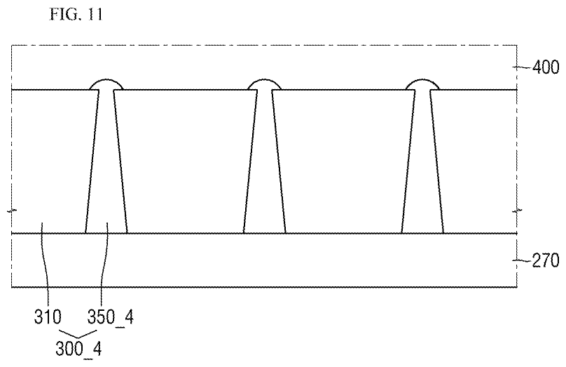

FIG. 11 is a cross-sectional view illustrating a thin film encapsulation layer, a viewing angle controlling member, and a touch member according to an embodiment.

Referring to FIG. 11, a viewing angle controlling member 300_4 according to the embodiment is different from the viewing angle controlling member 300 of FIG. 7 in that a viewing angle controlling pattern 350_4 of the viewing angle controlling member 300_4 of FIG. 11 protrudes upwards from the top surface of the light transmission pattern 310. For example, the viewing angle controlling pattern 350_4 of FIG. 11 may be partially disposed on the top surface of the light transmission pattern 310.

In more detail, a top surface of the viewing angle controlling pattern 350_4 of the viewing angle controlling member 300_4 of FIG. 11 may protrude upwards from the top surface of the light transmission pattern 310, and may partially overlap with the light transmission pattern 310. For example, the top surface of the viewing angle controlling pattern 350_4 may be partially disposed on the top surface of the light transmission pattern 310.

Other components and features in FIG. 11 are the same or substantially the same as those described above with reference to FIG. 7, and thus, redundant description thereof may not be repeated.

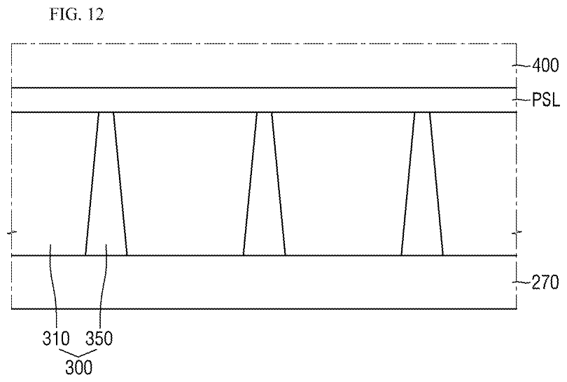

FIG. 12 is a cross-sectional view illustrating a thin film encapsulation layer, a viewing angle controlling member, and a touch member according to an embodiment.

Referring to FIG. 12, the embodiment shown is different from the embodiment of FIG. 7 in that a planarization layer PSL is further disposed between the touch member 400 and the viewing angle controlling member 300.

In more detail, the planarization layer PSL may include an organic insulating material. The planarization layer PSL may be disposed on the top surface of the viewing angle controlling member 300, and may planarize the top surface of the viewing angle controlling member 300 such that the touch member 400 may be disposed (e.g., or easily deposited) thereabove.

Other components and features in FIG. 12 are the same or substantially the same as those described above with reference to FIG. 7, and thus, redundant description thereof may not be repeated.

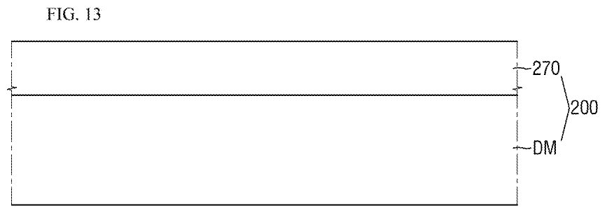

FIGS. 13 to 16 are cross-sectional views of a plurality of processing operations of a method of manufacturing a display according to an embodiment.

Referring to FIG. 13, the display member 200 is provided. In some embodiments, as described above, the display member 200 may include the base substrate 201, the light-emitting element ED disposed on the base substrate 201 for each of the pixels PX1, PX2, and PX3, and the thin film encapsulation layer 270 disposed on the light-emitting element ED.

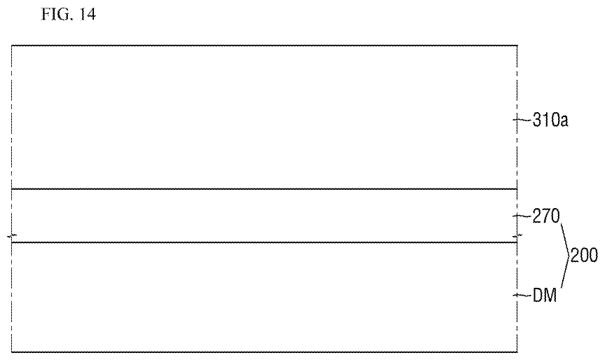

Referring to FIG. 14, a light transmission material 310a may be formed (e.g., may be directly formed) on the thin film encapsulation layer 270. The light transmission material 310a may include a transparent material. The transparent material may include, for example, a resin and/or a transparent photosensitive material. The resin may include, for example, PET, polyacrylate, PI, PC, and/or the like. The transparent photosensitive material may include, for example, a photoresist, and/or the like. The light transmission material 310a according to an embodiment may include a photoresist. For example, the light transmission material 310a may include (or may be) a dry photoresist without a solvent. In this case, the operation of forming the light transmission material 310a may further include an operation of forming the dry photoresist on the thin film encapsulation layer 270 using a lamination process.

However, the present disclosure is not limited thereto, for example, in some embodiments, the light transmission material 310a may include (or may be) a dry photoresist including a solvent. In this case, the operation of forming the light transmission material 310a may further include an operation of coating the thin film encapsulation layer 270 with a photoresist including a solvent, and removing the solvent.

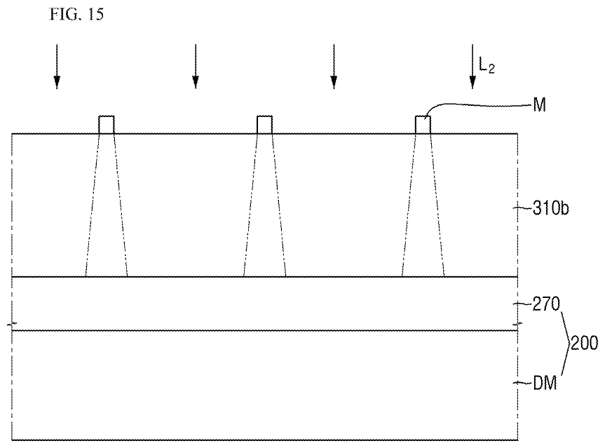

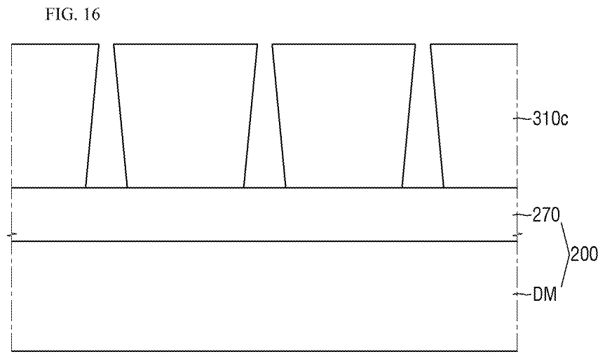

Referring to FIGS. 15 and 16, a light transmission pattern 310c is formed by exposing the light transmission material 310a to light, and developing the exposed light transmission material 310a. For example, a cured light transmission material 310b may be formed by exposing the light transmission material 310a to light. The operation of exposing the light transmission material 310a to light may include an operation of negatively exposing the light transmission material 310a using a mask M.

In the operation of negatively exposing the light transmission material 310a using the mask M, the mask M is located (or arranged) on (e.g., over) a desired or suitable area at (e.g., in or on) which the viewing angle controlling pattern 350 is to be formed, and ultraviolet rays L2 may be emitted toward the light transmission material 310a to form the cured light transmission material 310b.

Then, the light transmission material 310a of the cured light transmission material 310b is developed using a developing solution, and may be baked to form the light transmission pattern 310c. An opening is formed in the light transmission pattern 310c such that the top surface of the thin film encapsulation layer 270 may be exposed through the opening. The light transmission pattern 310c may be the same or substantially the same as the above-described light transmission pattern 310 of FIG. 7, and thus, redundant description thereof may not be repeated.

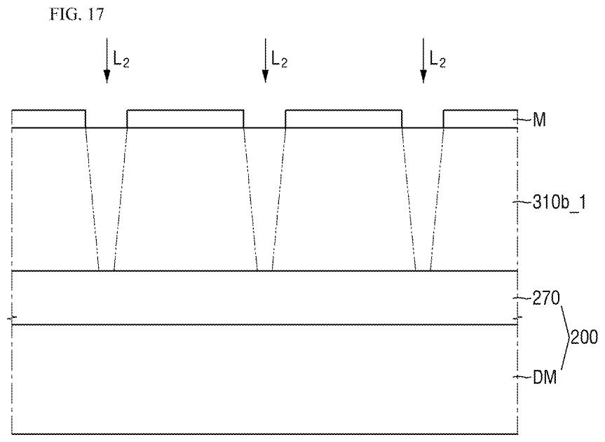

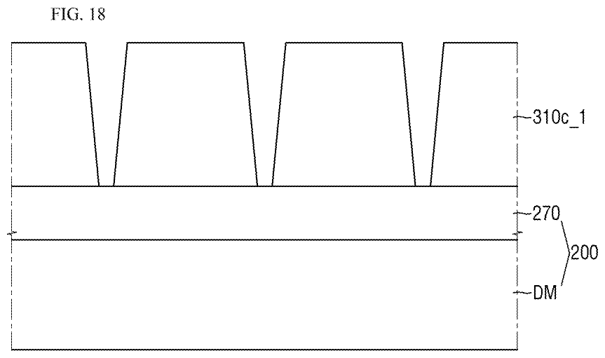

FIGS. 17 to 18 are cross-sectional views of a plurality of processing operations of a method of manufacturing a display according to an embodiment. A light transmission material 310b_1 may be formed by exposing the light transmission material 310a to light. The operation of exposing the light transmission material 310a to light may include an operation of positively exposing the light transmission material 310a using a mask M.

Referring to FIGS. 17 and 18, in the operation of positively exposing the light transmission material 310a using the mask M, the mask M is located (or arranged) on (e.g., over) a desired or suitable area at (e.g., in or on) which the viewing angle controlling pattern 350 is not to be formed, for example, an area at (e.g., in or on) which the light transmission pattern 310 is to be disposed, and ultraviolet rays L2 may be emitted toward the light transmission material 310a at (e.g., in or on) the area where the mask M is not located to form the light transmission material 310b_1.

Then, the light transmission material 310b_1 at the area where the mask M is not located is developed and removed, and the light transmission material 310a at the area where the mask M is located is baked such that a light transmission pattern 310c_1 of FIG. 18 may be formed. An opening is formed in the light transmission pattern 310c_1 such that the top surface of the thin film encapsulation layer 270 may be exposed through the opening. The light transmission pattern 310c_1 may be the same or substantially the same as the above-described light transmission pattern 310_1 of FIG. 8, and thus, redundant description thereof may not be repeated.

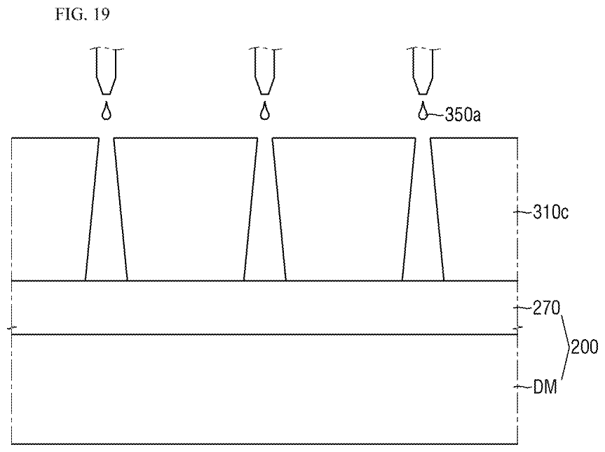

FIG. 19 is a cross-sectional view illustrating a processing operation of the method of manufacturing the display according to an embodiment.

Referring to FIG. 19, a viewing angle controlling material 350a is formed between the light transmission patterns 310c.

The viewing angle controlling material 350a may include a light-barrier material, for example, such as a dark-colored pigment (e.g., a black pigment and/or a gray pigment), a dark-colored dye (e.g., a black dye and/or a gray dye), carbon black, a photoresist, and/or the like.

The operation of forming the viewing angle controlling material 350a between the light transmission patterns 310 may further include an operation of forming the viewing angle controlling material 350a between the light transmission patterns 310 through an inkjet process or through a filling process.

As used herein, the operation of forming the viewing angle controlling material 350a between the light transmission patterns 310 through the filling process refers to a process in which the viewing angle controlling material 350a is disposed at an edge part of the display 1, and a gap between the light transmission patterns 310 is filled with the viewing angle controlling material 350a through a capillary phenomenon.

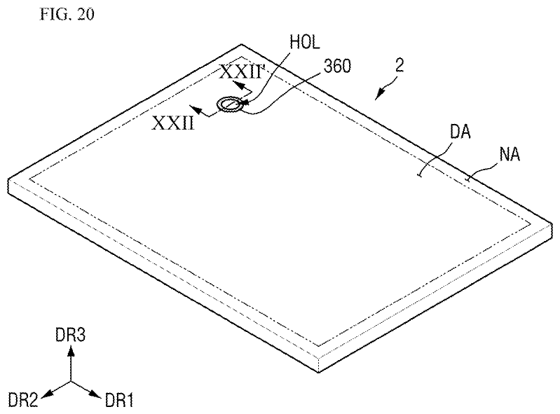

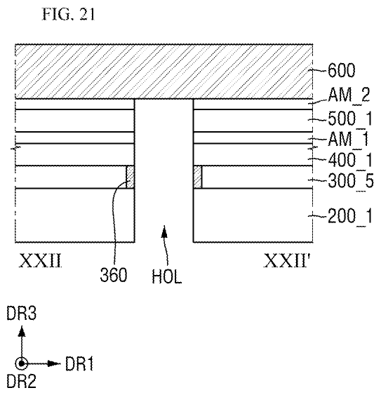

FIG. 20 is a perspective view of a display according to an embodiment, and FIG. 21 is a cross-sectional view of the display taken along the line XXII-XXII′ of FIG. 20.

Referring to FIGS. 20 and 21, the embodiment shown may be different from the embodiment of FIGS. 1 and 3 in that the display 2 according to the embodiment of FIGS. 20 and 21 further includes a through-hole HOL that extends (e.g., passes) through each of a display member 200_1, a viewing angle controlling member 300_5, a touch member 400_1, and an optical film 500_1.

The through-hole HOL may be formed beginning from a second optically transparent adhesive member AM_2 and extending (e.g., passing) through each of the lower members thereof in a thickness direction.

The viewing angle controlling member 300_5 may further include a hole-peripheral pattern 360 that surrounds (e.g., around a periphery of) the through-hole HOL in a plan view. The hole-peripheral pattern 360 may be located at (e.g., on) a periphery of the through-hole HOL, and may completely surround (e.g., around the periphery of) the through hole HOL in a plan view.

In some embodiments, as would be known to those skilled in the art, the viewing angle controlling member 300 shown in FIGS. 3 and 4 and the hole-peripheral pattern 360 may be disposed together.

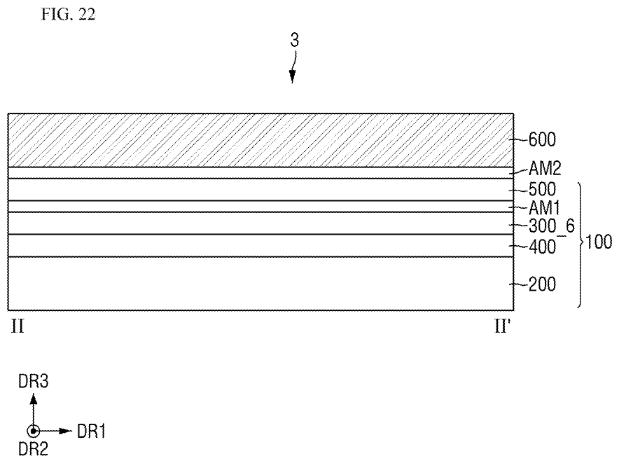

FIG. 22 is a cross-sectional view of a display according to an embodiment.

Referring to FIG. 22, the embodiment shown is different from the embodiment of FIG. 2 in that a viewing angle controlling member 300_6 of the display 3 of FIG. 22 according to the embodiment is disposed between the touch member 400 and the first optically transparent adhesive member AM1.

The viewing angle controlling member 300_6 may be in contact (e.g., in direct contact) with the third touch insulating layer 450 of the touch member 400. When the third touch insulating layer 450 is omitted, the viewing angle controlling member 300_6 may be in contact (e.g., in direct contact) with the top surface of the second touch conductive layer 440. Other components and features in FIG. 22 are the same or substantially the same as those described above with reference to FIGS. 2 and 3, and thus, redundant description thereof may not be repeated.

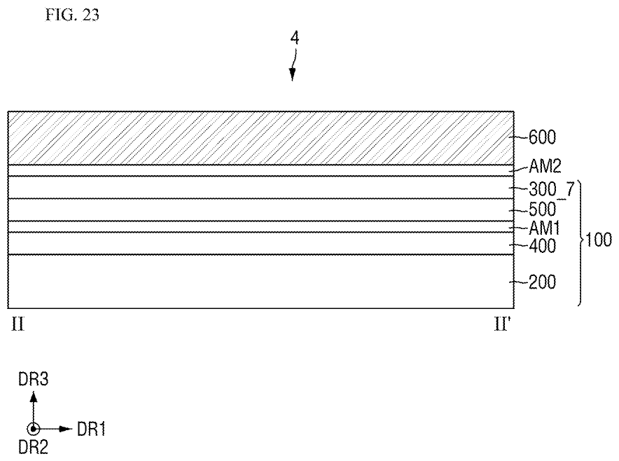

FIG. 23 is a cross-sectional view of a display according to an embodiment.

Referring to FIG. 23, the embodiment shown is different from the embodiment of FIG. 2 in that a viewing angle controlling member 300_7 of the display 4 in FIG. 23 according to the embodiment is disposed between the optical film 500 and the second optically transparent adhesive member AM2.

The viewing angle controlling member 300_7 may be disposed on (e.g., directly on) a top surface of the optical film 500. Other components and features of FIG. 23 are the same or substantially the same as those described above with reference to FIGS. 2 and 3, and thus, redundant description thereof may not be repeated.

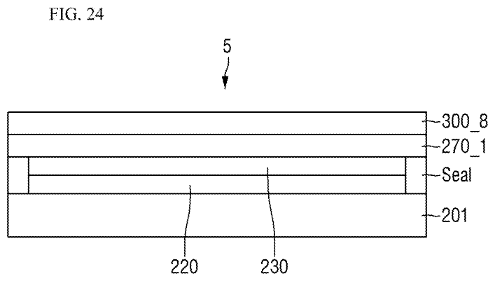

FIG. 24 is a cross-sectional view of a display according to an embodiment.

Referring to FIG. 24, a display 5 according to the embodiment is different from the display 1 of FIGS. 2 and 3 in that a rigid display panel is applied.

In more detail, the display 5 according to the embodiment includes a lower substrate 201 and an upper substrate 270_1 opposite to the lower substrate 201. The display 5 may include a circuit driving layer 220 disposed between the lower substrate 201 and the upper substrate 270_1, and an organic light-emitting element layer 230 disposed between the circuit driving layer 220 and the upper substrate 270_1.

The lower substrate 201 and the upper substrate 270_1 may be rigid substrates. The upper substrate 270_1 may include, for example, glass, quartz, and/or the like. The upper substrate 270_1 may generally overlap with the lower substrate 201 as shown in FIG. 24. A sealing member Seal is disposed at (e.g., on) edges and at (e.g., on) outer parts of the upper substrate 270_1 and the lower substrate 201, and couples the upper substrate 270_1 with the lower substrate 201, but the present disclosure is not limited thereto. An edge part of the upper substrate 270_1 protrudes downward such that a protruding part of the upper substrate 270_1 may be coupled with the lower substrate 201 through a sealing member and/or the like.

The circuit driving layer 220 may include the TFT and the like described above with reference to FIGS. 2 and 3, and the organic light-emitting element layer 230 may include the light-emitting element ED and the like described above with reference to FIGS. 2 and 3. Other components and features of FIG. 24 are the same or substantially the same as those described above with reference to one or more embodiments, and thus, redundant description thereof may not be repeated.

A viewing angle controlling member 300_8 may be disposed on (e.g., directly on) a top surface of the upper substrate 270_1. Because the viewing angle controlling member 300_8 may be the same or substantially the same as those described above with reference to one or more embodiments, redundant description thereof may not be repeated.

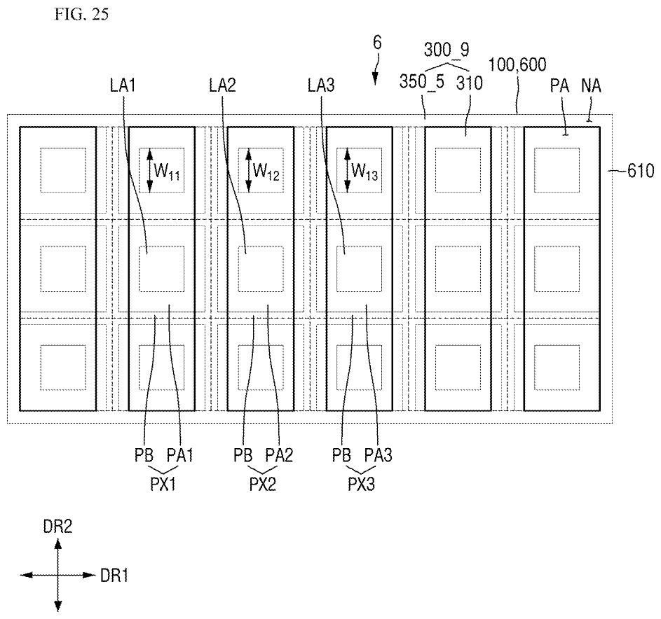

FIG. 25 is an arrangement plan view of a display according to an embodiment.

Referring to FIG. 25, in a display 6 according to the embodiment, a viewing angle controlling member 300_9 may be different from the viewing angle controlling member 300 of FIG. 4 in that a viewing angle controlling pattern 350_5 of the viewing angle controlling member 300_9 in FIG. 25 is disposed along the non-display area NA, for example, an edge (or a bezel) of the display 6, and has a stripe shape extending in the second direction DR2 crossing the first direction DR1.

Other components and features in FIG. 25 are the same or substantially the same as those described above with reference to FIG. 4, and thus, redundant description thereof may not be repeated.

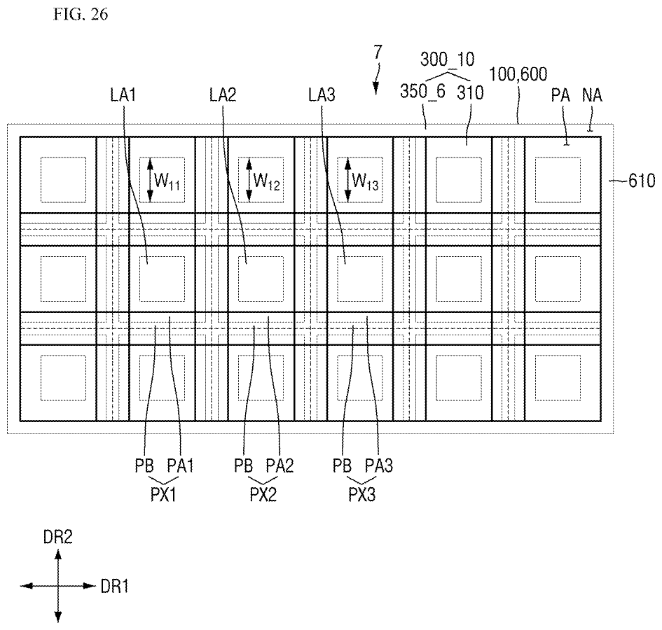

FIG. 26 is an arrangement plan view of a display according to an embodiment.

Referring to FIG. 26, in a display 7 according to the embodiment, a viewing angle controlling member 300_10 may be different from the viewing angle controlling member 300 of FIG. 4 in that a viewing angle controlling pattern 350_6 of the viewing angle controlling member 300_10 may be disposed along the non-display area NA, for example, an edge (or a bezel) of the display 7, and has a lattice shape extending in the first direction DR1 and the second direction DR2.

Other components and features in FIG. 26 are the same or substantially the same as those described above with reference to FIG. 4, and thus, redundant description thereof may not be repeated.

In a display and a method of manufacturing the same according to one or more embodiments of the present disclosure, a viewing angle controlling pattern may be embedded in a display panel so as to reduce a transmission loss.

In some embodiments, the viewing angle control pattern may be disposed to not overlap with LEDs of the display panel so as to reduce a light loss.

In some embodiments, a degree of freedom in a shape of the viewing angle controlling pattern may be increased.

Aspects and features of the present disclosure are not limited to those described above with reference to the exemplary embodiments, and various other aspects and features may be included in the present disclosure.

Accordingly, while various exemplary embodiments of the present invention have been described with reference to the attached drawings, it should be understood by one of ordinary skill in the art that the embodiments described herein should be considered in a descriptive sense only and not for purposes of limitation. Accordingly, those with ordinary skill in the art to which the present invention pertains will understand that various aspect and features of the present invention may be modified without departing from the spirit and scope of the present invention as defined in the following claims, and their equivalents.

What is claimed is:

1. A display comprising:
a display member at which a plurality of pixels are defined, the display member comprising a base substrate, a light-emitting element on the base substrate at each pixel, and a thin film encapsulation layer on the light-emitting element;
a viewing angle controlling member on the display member, the viewing angle controlling member comprising a plurality of viewing angle controlling patterns; and
a cover window on the plurality of viewing angle controlling patterns,
wherein the plurality of viewing angle controlling patterns are directly on the thin film encapsulation layer.

2. The display of claim 1, wherein the viewing angle controlling patterns comprise at least one of a black-based dye and a metal.

3. The display of claim 2, wherein the viewing angle controlling member further comprises a light transmission pattern between adjacent ones of the viewing angle controlling patterns, the light transmission pattern comprising a transparent photosensitive material.

4. The display of claim 3, wherein a height of at least one of the viewing angle controlling patterns is equal to two or three times a pitch between the adjacent ones of the viewing angle controlling patterns.

5. The display of claim 3, wherein at least one of the viewing angle controlling patterns has a forward-tapered shape, and an inclined angle between a top surface of the thin film encapsulation layer and a side surface of the at least one of the viewing angle controlling patterns is within a range of 91° to 110°.

6. The display of claim 3, wherein at least one of the viewing angle controlling patterns has a reverse-tapered shape, and an inclined angle between a top surface of the thin film encapsulation layer and a side surface of the at least one of the viewing angle controlling patterns is within a range of 85° to 89°.

7. The display of claim 3, wherein a height of a surface of at least one of the viewing angle controlling patterns is less than a height of a surface of the light transmission pattern.

8. The display of claim 7, wherein the surface of the at least one of the viewing angle controlling patterns includes a concave shape or a convex shape.

9. The display of claim 3, wherein a height of a surface of at least one of the viewing angle controlling patterns is greater than a height of a surface of the light transmission pattern, and the at least one of the viewing angle controlling patterns partially covers a top surface of the light transmission pattern.

10. The display of claim 1, wherein the light-emitting element comprises a first electrode on the base substrate, a second electrode opposite to the first electrode, and a light-emitting layer between the first electrode and the second electrode, and
wherein each of the pixels comprises a light-emitting area at which a top surface of the first electrode is partially exposed by a pixel definition film on the first electrode, a non-emitting area is defined at a periphery of the light-emitting area, and each of the viewing angle controlling patterns is at the non-emitting area.

11. The display of claim 10, wherein each of the viewing angle controlling patterns does not overlap with the light-emitting area of an adjacent pixel.

12. The display of claim 10, wherein a height of the viewing angle controlling patterns is greater than a width of the light-emitting area of an adjacent pixel.

13. The display of claim 12, wherein each of the pixels comprises a light-exit area comprising the light-emitting area and a non-exit area at a periphery of the light-exit area,
wherein the display further comprises a light-barrier pattern at the non-exit area on the cover window, and
wherein the light-barrier pattern overlaps with a corresponding one of the viewing angle controlling patterns in a thickness direction.

14. The display of claim 13, further comprising:
long-side edges extending in a first direction; and
short-side edges extending in a second direction crossing the first direction,
wherein the plurality of viewing angle controlling patterns have a stripe shape extending in the first direction.

15. The display of claim 14, wherein the viewing angle controlling patterns are continuously arranged on a border along the long-side edges and the short-side edges.

16. The display of claim 13, further comprising:
long-side edges extending in a first direction; and
short-side edges extending in a second direction crossing the first direction,
wherein the plurality of viewing angle controlling patterns have a stripe shape extending in the second direction.

17. The display of claim 13, further comprising:
long-side edges extending in a first direction; and
short-side edges extending in a second direction crossing the first direction,
wherein the plurality of viewing angle controlling patterns have a lattice shape extending in the first direction and the second direction.

18. The display of claim 13, further comprising a through-hole extending through the display member and the viewing angle controlling member in a thickness direction,
wherein the viewing angle controlling patterns surround the through-hole.

19. The display of claim 1, further comprising:
a touch member on the plurality of viewing angle controlling patterns; and
a polarization layer on the touch member.

20. A display comprising:
a display member at which a plurality of pixels are defined, the display member comprising a base substrate, a light-emitting element on the base substrate at each pixel, and a thin film encapsulation layer on the light-emitting element;
a touch member on the display member;
a polarization layer on the touch member;
a viewing angle controlling member on the display member, the viewing angle controlling member comprising a plurality of viewing angle controlling patterns; and
a cover window on the plurality of viewing angle controlling patterns,
wherein the light-emitting element comprises:
a first electrode on the base substrate;
a second electrode opposite to the first electrode; and
a light-emitting layer between the first electrode and the second electrode,
wherein each of the pixels comprises a light-emitting area at which a top surface of the first electrode is partially exposed by a pixel definition film on the first electrode, a non-emitting area is defined at a periphery of the light-emitting area, and each of the viewing angle controlling patterns is at the non-emitting area, and
wherein each of the viewing angle controlling patterns does not overlap with the light-emitting area of an adjacent pixel.

21. The display of claim 20, wherein the viewing angle controlling patterns comprise at least one of a black-based dye, a black-based pigment, and a metal.

22. The display of claim 21, wherein the viewing angle controlling member further comprises a light transmission pattern between adjacent ones of the viewing angle controlling patterns, the light transmission pattern comprising a transparent photosensitive material.

23. The display of claim 20, wherein the viewing angle controlling member is between the touch member and the polarization layer, or the viewing angle controlling member is between the polarization layer and the cover window.

24. A method of manufacturing a display, comprising:
providing a display member comprising a base substrate, a light-emitting element on the base substrate in each pixel, and a thin film encapsulation layer on the light-emitting element;
forming a photoresist directly on the thin film encapsulation layer;
forming a plurality of light transmission patterns by exposing the photoresist to light and developing the exposed photoresist; and
forming a viewing angle controlling pattern between adjacent ones of the light transmission patterns,
wherein the viewing angle controlling pattern is in direct contact with the thin film encapsulation layer.

25. The method of claim 24, wherein the exposing of the photoresist comprises positively exposing the photoresist using a mask, or negatively exposing the photoresist using a mask.

26. The method of claim 24, wherein the forming of the viewing angle controlling pattern between adjacent ones of the light transmission patterns comprises forming the viewing angle controlling pattern between adjacent ones of the light transmission patterns through an inkjet process or through a filling process using a black-based material.
